(19) United States
(12) Patent Application Publication
(10) Pub. No.: US 2025/0257998 A1
(43) Pub. Date: Aug. 14, 2025

(54) MICROELECTROMECHANICAL GYROSCOPE WITH FULLY DIFFERENTIAL STRUCTURE AND PITCH/ROLL SENSING

(71) Applicant: STMicroelectronics International N.V., Geneva (CH)

(72) Inventors: Patrick FEDELI, Senago (IT); Luca Giuseppe FALORNI, Limbiate (MB) (IT); Gabriele GATTERE, Castronno (Varese) (IT)

(73) Assignee: STMicroelectronics International N.V., Geneva (CH)

(21) Appl. No.: 19/046,926

(22) Filed: Feb. 6, 2025

(30) Foreign Application Priority Data
Feb. 12, 2024 (IT) 102024000002890

(51) Int. Cl. G01C 19/5747; B81B 3/00

(52) U.S. Cl. CPC G01C 19/5747; B81B 3/0018; B81B 2201/0242

(57) ABSTRACT

A microelectromechanical gyroscope includes a support body having a main surface parallel to a reference plane defined by a first axis and a second axis perpendicular to each other. Transduction masses are constrained to the support body so as to be capable of oscillating along a driving direction parallel to the first axis and along a third axis perpendicular to the first axis and the second axis. Sensing masses are constrained to the support body at a distance from the substrate so as to be capable of oscillating in a direction parallel to the second axis. Motion conversion flexures connect the transduction masses to respective sensing masses and are configured so as to convert movements of the transduction masses along the third axis into movements of the respective sensing masses along the second axis.

### PRIORITY CLAIM

This application claims the priority benefit of Italian Application for Patent No. 102024000002890 filed on Feb. 12, 2024, the content of which is hereby incorporated by reference in its entirety to the maximum extent allowable by law.

### TECHNICAL FIELD

This disclosure relates to a microelectromechanical gyroscope with fully differential structure and pitch/roll sensing.

### BACKGROUND

As is known in the field of microelectromechanical gyroscopes, the design of the devices needs to meet increasingly stringent market demands, for example so as to the increase in scale factor stability and vibration rejection performance. Applications where scale factor stability and vibration rejection are particularly important include those relating to autonomous inertial navigation for the automotive sector. The scale factor defines the sensitivity of the gyroscope and should be stable during the life of the sensor. However, external factors such as variations in temperature (also during the production step due to soldering on printed circuit board—PCB) or humidity and mechanical stress may affect the scale factor and, consequently, the accuracy of the measurements.

In a MEMS gyroscope, the scale factor is directly correlated to the distance at rest between fixed or stator sensing electrodes and movable sensing electrodes. If the support body deforms, the distance at rest between fixed and movable sensing electrodes is altered and variations affect the sensitivity of the sensor.

A known solution to the scale factor stability issue envisages a fully differential sensing architecture that compensates for sensitivity variation. In a fully differential architecture, in fact, each movable sensing electrode is differentially coupled to two respective fixed sensing electrodes. This allows the pairs of fixed sensing electrodes to be placed at a short distance from the movable sensing electrode respectively associated, so as to reduce the effects of deformations of the support body. The rejection of common-mode contributions may thus be improved, and the differential contributions may thus be amplified.

This solution is easily practicable in gyroscopes that sense rotations around a yaw axis perpendicular to the support body and have a typically in-plane-type sensing structure. Gyroscopes that sense rotations around roll or pitch axes, instead, have an out-of-plane-type sensing structure and the available fully differential architectures may be less satisfactory in some respects. For the same silicon area occupied, in particular, the out-of-plane sensing structures have lower sensitivity with respect to in-plane sensing structures, because the sensing electrodes substantially develop in planes parallel to the main face of the support body. Conversely, in-plane sensing structures may generally also exploit the development of the sensing electrodes in a direction perpendicular to the support body. Furthermore, in-plane-type sensing structures still have fixed sensing electrodes that are on average closer and are therefore less subject to the effects of deformations of the support body, as already observed.

There is a need in the art to provide a microelectromechanical gyroscope which allows the limitations described to be overcome or at least mitigated.

### SUMMARY

In an embodiment, a microelectromechanical gyroscope includes a support body having a main surface parallel to a reference plane defined by a first axis and a second axis perpendicular to each other. The gyroscope has a plurality of transduction masses constrained to the support body so as to be capable of oscillating along a driving direction parallel to the first axis and along a third axis perpendicular to the first axis and the second axis. The gyroscope has a plurality of sensing masses constrained to the support body at a distance from a substrate so as to be capable of oscillating in a direction parallel to the second axis. The gyroscope has a plurality of motion conversion flexures, each motion conversion flexure connecting one of the plurality of transduction masses to one of the plurality of sensing masses and configured to convert movements of the one of the plurality of transduction masses along the third axis into movements of the one of the plurality of sensing masses along the second axis.

The plurality of transduction masses may include a first transduction mass and a second transduction mass arranged symmetrically opposite to each other, in rest conditions, with respect to a reference axis parallel to the first axis. The gyroscope may include a plurality of first anchors fixed to the support body and a plurality of oscillating arms, each oscillating arm of the plurality of oscillating arms supported by one of the plurality of first anchors around a fulcrum so as to oscillate parallel to the reference plane, where the fulcrums are aligned along the reference axis in symmetrically opposite positions with respect to a median axis of the plurality of transduction masses parallel to the second axis. The first transduction mass and the second transduction mass may be supported by the plurality of oscillating arms so as to be movable parallel to the first axis and parallel to the third axis.

The plurality of oscillating arms may be coupled to the plurality of transduction masses so as to allow phase-opposition movements and prevent in-phase movements of the first transduction mass and the second transduction mass along the first axis. Each oscillating arm of the plurality of oscillating arms may have a first end connected to the first transduction mass and a second end connected to the second transduction mass through a plurality of first suspension flexures, where the plurality of first suspension flexures are configured to convey movements from the first and second ends of the plurality of oscillating arms to the first and second transduction masses in the direction of the first axis.

Each oscillating arm of the plurality of oscillating arms may be coupled to one of the plurality of first anchors with its fulcrum in a symmetrically opposite position with respect to the median axis. The gyroscope may include a plurality of second anchors and a plurality of second suspension flexures, where each sensing mass of the plurality of sensing masses is supported by one of the plurality of second anchors through one of the plurality of second suspension flexures, and where the plurality of second suspension flexures are yielding in the direction of the second axis and rigid in the direction of the first axis and the third axis.

The plurality of sensing masses may include a first sensing mass and a second sensing mass coupled to the first transduction mass, and a third sensing mass and a fourth sensing mass coupled to the second transduction mass, where the first and second sensing masses are adjacent to opposite sides of the first transduction mass, and the third and fourth sensing masses are adjacent to opposite sides of the second transduction mass. The second sensing mass and the third sensing mass may form a single rigid body.

The motion conversion flexures connecting the first transduction mass to the first and second sensing masses may be configured to cause movements of the first and second sensing masses in phase-opposition in response to displacements of the first transduction mass along the third axis. The motion conversion flexures connecting the second transduction mass to the third and fourth sensing masses may be symmetrical to each other and may be configured to cause movements of the third and fourth sensing masses in phase-opposition in response to displacements of the second transduction mass along the third axis.

Each motion conversion flexure of the plurality of motion conversion flexures may have an elongated shape in the direction of the first axis, a first end connected to one of the plurality of transduction masses, and a second end connected to one of the plurality of sensing masses. The first end of each motion conversion flexure may be coupled to its associated transduction mass through a connection flexure that is rigid along the third axis and yielding along the driving direction parallel to the first axis.

The plurality of motion conversion flexures may be of a skew bending type. Each motion conversion flexure of the plurality of motion conversion flexures may include a first elastic body, a second elastic body, and a plurality of transverse elements. The first elastic body and the second elastic body may be defined by flat rectangular plates, in rest conditions perpendicular to the second axis and elongated in the direction of the first axis. The first elastic body and the second elastic body may be offset with respect to each other in the direction of the second axis and in the direction of the third axis.

The plurality of transverse elements may be defined by flat plates in rest conditions perpendicular to the first axis. The plurality of transverse elements may be uniformly spaced along the first axis. Each transverse element of the plurality of transverse elements may have a first side connected to the first elastic body and a second side, opposite to the first side, connected to the second elastic body.

### BRIEF DESCRIPTION OF THE DRAWINGS

For a better understanding, embodiments are presented, by way of non-limiting example, with reference to the attached drawings, wherein:

FIG. 1 is a block diagram of a microelectromechanical gyroscope;

FIG. 2 is a top-plan view of a microstructure of the gyroscope of FIG. 1;

FIG. 3 is a cross-section of the microstructure of FIG. 2, taken along the line III-III of FIG. 2, in a first operating configuration;

FIG. 4 shows the view of FIG. 3, with the microstructure in a second operating configuration;

FIG. 5 is a top-plan view of an enlarged detail of the microstructure of FIG. 2;

FIG. 6 is a partial perspective view of the detail of FIG. 5;

FIGS. 7a-7c are respectively a first, a second and a third cross-section of the detail of FIG. 5 in the first operating configuration; and

FIGS. 8a-8c show the views respectively of FIGS. 7a-7c in the second operating configuration.

### DETAILED DESCRIPTION

The following description refers to the arrangement shown in the drawings; consequently, expressions such as “above”, “below”, “upper”, “lower”, “top”, “bottom”, “right”, “left” and the like relate to the attached Figures and are not to be interpreted in a limiting manner.

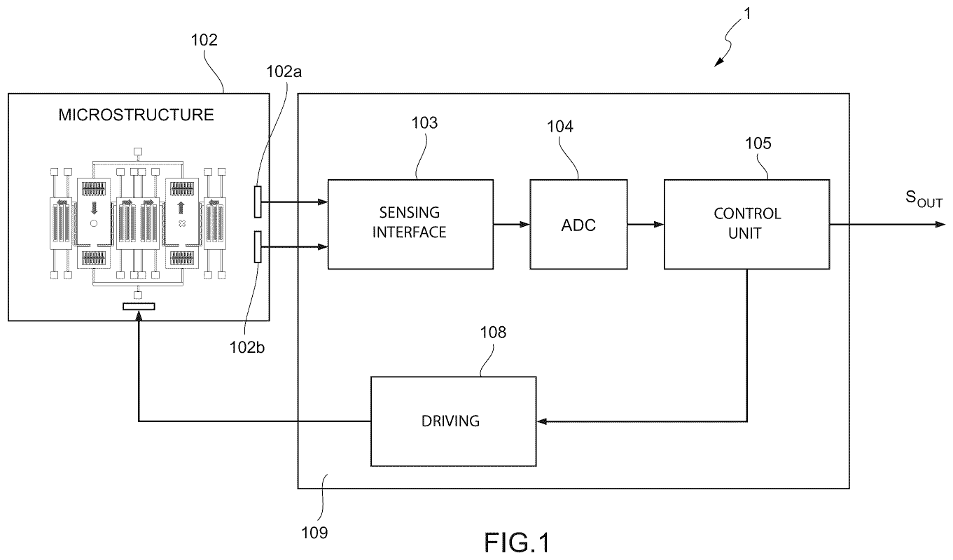

With reference to FIG. 1, a microelectromechanical gyroscope in accordance with an embodiment is indicated as a whole by the numeral 1 and comprises a microstructure 102, a sensing interface 103, an analog-to-digital converter 104, a control unit 105 and a driving stage 108. The sensing interface 103, the analog-to-digital converter 104, the control unit 105 and the driving stage 108 may be components of a dedicated integrated circuit or ASIC (Application Specific Integrated Circuit) 109 coupled to the microstructure 102.

The sensing interface 103 receives sensing signals from a first sensing terminal 102a and a second sensing terminal 102b of the microstructure 2, respectively, and provides amplified sensing signals, usable by the analog-to-digital converter 104 to generate digital sensing signals.

The control unit 105 processes the digital sensing signals and provides an output signal SOUT indicative of an angular velocity around a sensing axis (not shown), measured through the microstructure 102.

The driving stage 108 is controlled by the control unit 105 and provides a driving voltage VD to maintain movable portions of the microstructure 102 oscillating with a driving frequency ωD that is constant and close to a resonance frequency of the same microstructure 102.

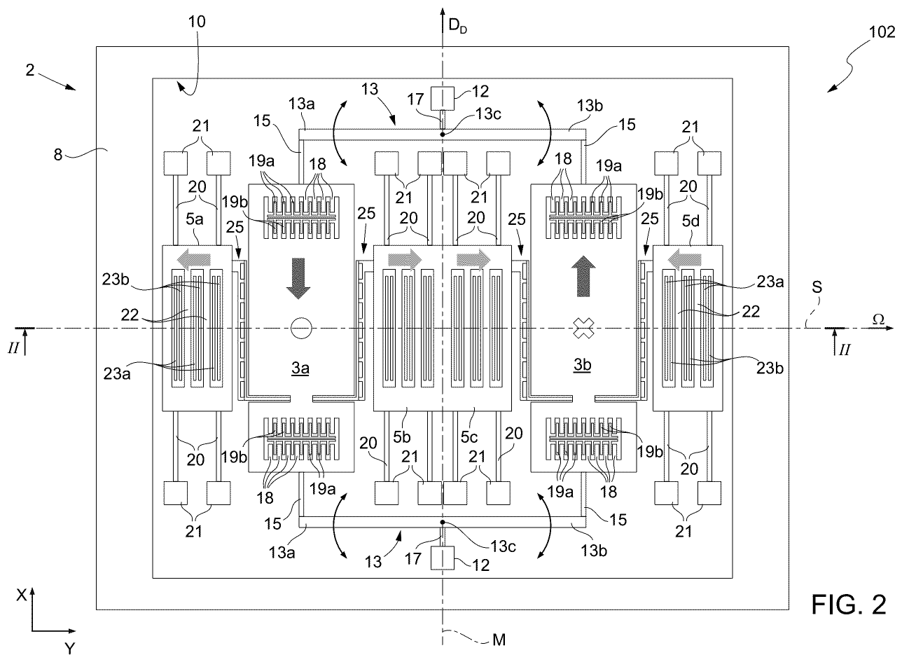

With reference to FIGS. 2-4, the microstructure 102 comprises a support body 2, transduction masses 3a, 3b and sensing masses 5a-5d, movable with respect to the support body 2.

The support body 2 has a main surface 2a parallel to a plane XY defined by a first axis X and a second axis Y of a set of three Cartesian axes and perpendicular to a third axis Z of the set of three. The support body 2 may comprise, for example, a substrate 7 and a frame structure 8, formed on the substrate 7 and laterally delimiting a cavity 10 where the transduction masses 3a, 3b and the sensing masses 5a-5d are accommodated. The cavity 10 is also delimited at the bottom by the substrate 7. The substrate 7 and the frame structure 8 are of semiconductor material, for example respectively monocrystalline and polycrystalline silicon.

The transduction masses 3a, 3b and the sensing masses 5a-5d, also of semiconductor material, are elastically connected to the support body 2 so as to be capable of oscillating in accordance with respective predetermined degrees of freedom with respect to a reference axis M, which is parallel to the first axis X (and therefore to the main surface 2a of the support body 2) and perpendicular to a sensing axis S. The sensing axis S is a median axis of the transduction masses 3a, 3b (in rest conditions) and is parallel to the second axis Y.

In detail, the transduction masses comprise a first transduction mass 3a and a second transduction mass 3b arranged symmetrically opposite, in rest conditions, with respect to the reference axis M. The first transduction mass 3a and the second transduction mass 3b are suspended at a distance from the substrate 7 and are supported by anchors 12 and two oscillating arms 13 so as to be movable with respect to the support body along a driving direction DD parallel to the first axis X and along a transduction direction DT parallel to the third axis Z. In one embodiment, in particular, the anchors 12 are placed along the reference axis M and are symmetrically opposite to the sensing axis S. The oscillating arms 13, having an elongated shape in the direction of the second axis Y, are also arranged symmetrically opposite with respect to the sensing axis S and each have a first end 13a, a second end 13b and a fulcrum 13c. The first ends 13a and the second ends 13b of the oscillating arms 13 are connected to the first transduction mass 3a and the second transduction mass 3b, respectively, by suspension flexures 15 configured to convey movements from the ends 13a, 13b of the oscillating arms 13 to the transduction masses 3a, 3b in the direction of the first axis X. In the direction of the second axis Y, instead, the suspension flexures 15 are almost rigid and the deformations are limited to what is useful to accommodate the movements of the oscillating arms 13. The fulcrums 13c of the oscillating arms 13 are coupled to the respective anchors 12 by suspension flexures 17 and are aligned along the reference axis M in positions symmetrically opposite with respect to the sensing axis S. The suspension flexures 17 are configured so that the oscillating arms 13 may oscillate in the plane XY parallel to the main surface 2a around the respective fulcrums 13a. The suspension flexures 17 instead prevent the translation of the fulcrums 13c in a direction parallel to the first axis X. Consequently, the oscillating arms 13 coordinate and allow the phase-opposition or differential movement of the first transduction mass 3a and the second transduction mass 3b parallel to the first axis X (in practice, discordant displacements of equal amplitude, but in opposite directions along the first axis X). Conversely, in-phase or common-mode movements are prevented (i.e., the oscillating arms 13 prevent the first transduction mass 3a and the second transduction mass 3b from moving simultaneously in a concordant manner in the same direction along the first axis X).

The transduction masses 3a, 3b are also provided with movable sensing electrodes 18, capacitively coupled, for example in comb fingered configuration, to respective groups of fixed driving electrodes 19a, 19b rigidly anchored to the support body 2. In particular, the movable driving electrodes 18 and the fixed driving electrodes 19a, 19b are shaped and coupled so as to apply, in response to the driving voltage VD provided by the driving stage 108, electrostatic forces to the transduction masses 3a, 3b oriented according to the first axis X, in the driving direction DD. The driving voltage VD is applied to the first transduction mass 3a and the second transduction mass 3b with opposite polarities, so that the electrostatic forces are also opposite and cause oscillations of the first transduction mass 3a and the second transduction mass 3b at the driving frequency and in phase-opposition. Due to the driving and the degrees of freedom, the transduction masses 3a, 3b transduce rotations around the sensing axis S, which is parallel to the plane XY and perpendicular to the reference axis M, into movements along the transduction direction DT, parallel to the third axis Z. In other words, when the support body 2 rotates around the sensing axis with an angular velocity Ω, the transduction masses 3a, 3b oscillate along the third axis Z at the driving frequency ωD and with an amplitude modulated by the angular velocity Ω.

The sensing masses, identical to each other, comprise a first sensing mass 5a and a second sensing mass 5b, coupled to the first transduction mass 3a, and a third sensing mass 5c and a fourth sensing mass 5d, coupled to the second transduction mass 3b. The first sensing mass 5a and the second sensing mass 5b are adjacent to respective opposite sides of the first transduction mass 3a; similarly, the third sensing mass 5c and the fourth sensing mass 5d are adjacent to respective opposite sides of the second transduction mass 3b. In the direction of the second axis Y, therefore, the first transduction mass 3a is interposed between the first sensing mass 5a and the second sensing mass 5b; and the second transduction mass 3b is interposed between the third sensing mass 5c and the fourth sensing mass 5d. The second sensing mass 5b and the third sensing mass 5c are further interposed between the first transduction mass 3a and the second transduction mass 3b and, in one embodiment, form a single rigid body.

The sensing masses 5a-5d are suspended at a distance from the substrate 7 and are supported by respective anchors 20 and suspension flexures 21. In particular, the suspension flexures 21 are yielding in the direction of the second axis Y and substantially rigid in the direction of the first axis X and the third axis Z. As a result, the sensing masses 5a-5d are movable with respect to the support body 2 in the direction parallel to the second axis Y and the sensing axis S.

The sensing masses 5a-5d are provided with movable sensing electrodes 22 capacitively coupled to respective first fixed sensing electrodes 23a and second fixed sensing electrodes 23b, which are rigidly anchored to the support body 2. More precisely, the movable sensing electrodes 22 and the fixed sensing electrodes 23a, 23b are defined by plates or flat surfaces perpendicular to the second axis Y and form capacitors having variable capacitance depending on the position of the sensing masses 5a-5d with respect to the second axis Y. Furthermore, the first fixed sensing electrodes 23a and the second fixed sensing electrodes 23b are coupled to the first sensing terminal 102a and the second sensing terminal 102b of the microstructure 102, respectively.

The sensing masses 5a-5d are connected to the respective transduction masses 3a, 3b through motion conversion flexures 25 having skew bending, configured so as to convert the motion of the transduction masses 3a, 3b along the third axis Z into a motion of the sensing masses 5a-5d along the sensing axis S, i.e., in a direction parallel to the second axis Y. The skew bending is a strain to which a body may be subject when the axis of an applied moment does not coincide with a main axis of inertia. In this case, the inflection plane of the body does not coincide with the stress plane. The skew bending may be considered composed of two straight bendings having a moment axis coincident with a main axis of inertia.

The motion conversion flexures 25 have an elongated shape in the direction of the first axis X and each connect a respective transduction mass 3a, 3b and a respective sensing mass 5a-5d. More precisely, the motion conversion flexures 25 have a first end connected to the respective transduction mass 3a, 3b and a second end connected to the respective sensing mass 5a-5d. Furthermore, the motion conversion flexures 25 connecting the first transduction mass 3a to the first sensing mass 5a and to the second sensing mass 5b are symmetrical to each other and are configured to cause movements of the first sensing mass 5a and the second sensing mass 5b in phase-opposition (i.e., of equal amplitude, but in opposite directions along the second axis Y) in response to displacements of the first transduction mass 3a along the third axis Z; similarly, the motion conversion flexures 25 connecting the second transduction mass 3b to the third sensing mass 5c and the fourth sensing mass 5d are symmetrical to each other and are configured to cause movements of the third sensing mass 5c and the fourth sensing mass 5d in phase-opposition in response to movements of the second transduction mass 3b along the third axis Z. Furthermore, the motion conversion flexures 25 which connect the second sensing mass 5b to the first transduction mass 3a and the third sensing mass 5c to the second transduction mass 3b are symmetrical to each other with respect to the reference axis M (in rest conditions).

In detail, in one embodiment the first ends of the motion conversion flexures 25 are coupled to the respective transduction masses 3a, 3b through connection flexures 26, yielding in the direction of the first axis X and rigid in the direction of the second axis Y and the third axis Z. In practice, the connection flexures 26 convey the movement of the transduction masses 3a, 3b along the third axis Z to the first ends of the respective motion conversion flexures 25 in an almost rigid manner. The first ends of the motion conversion flexures 25 therefore follow the movement of the respective transduction masses 3a, 3b along the transduction direction DT and the third axis Z. The connection flexures 26 instead allow the relative movement of the transduction masses 3a, 3b with respect to the motion conversion flexures 25 along the driving direction DD, parallel to the first axis X. The transduction masses 3a, 3b may therefore oscillate due to the driving along the first axis X without altering the state of the motion conversion flexures 25, while the motion along the third axis Z is conveyed and converted into a corresponding motion along the sensing axis S, in a direction parallel to the second axis Y. Recesses 28 obtained in the sides of the transduction masses 3a, 3b and extending longitudinally in the direction of the second axis Y accommodate part of the connection flexures 26, which may therefore have the desired length and yielding in accordance with the design preferences.

In rest conditions, the first ends of the motion conversion flexures 25 are aligned in a direction parallel to the second axis Y.

Both by arrangement and by action of the motion conversion flexures 25, the sensing masses 5a-5d, the movable sensing electrodes 22 and the fixed sensing electrodes 23a, 23b form a fully differential sensing structure of in-plane type.

For example, the motion conversion flexures 25 may be formed substantially as described in U.S. Pat. No. 11,993,509 (corresponding to European Patent No. 3,872,451), in the name of the Applicant, the contents of both of which are incorporated by reference in their entirety. Hereinafter, for simplicity, reference will be made to only one of the motion conversion flexures 25, for example the one connecting the first transduction mass 3a to the first sensing mass 5a, meaning however that what has been stated also applies to all the others.

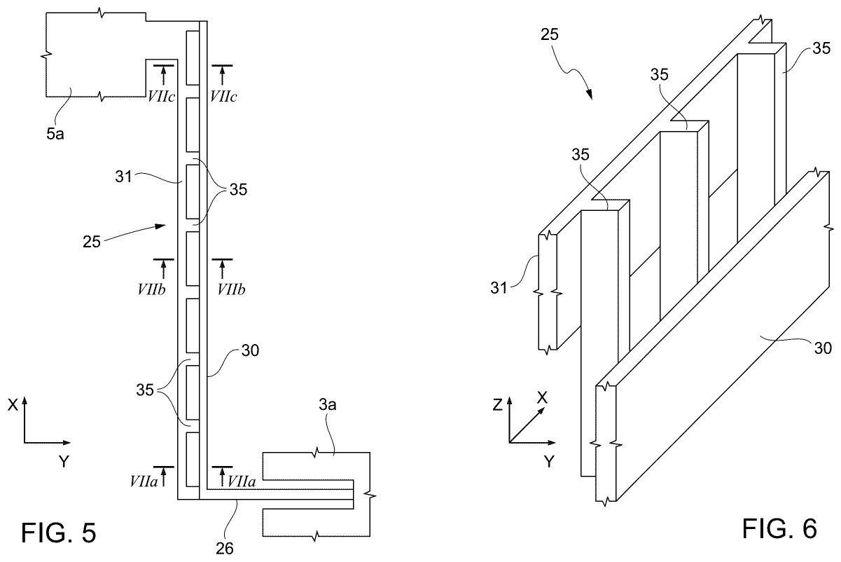

With reference also to FIGS. 5 and 6, the motion conversion flexure 25 comprises a first elastic body 30, a second elastic body 31 and a plurality of transverse elements 35, all of which are formed for example of the same semiconductor material as the substrate 7 and the frame structure 8 and form a single piece.

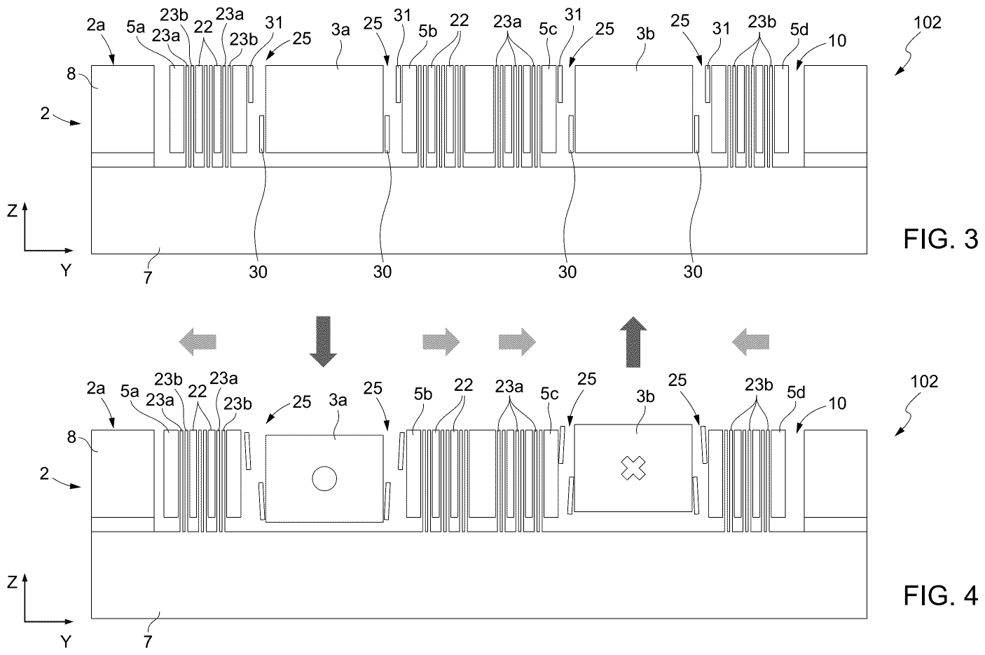

The first elastic body 30 and the second elastic body 31 are defined by flat rectangular plates of the same shape, in rest conditions perpendicular to the second axis Y and elongated in the direction of the first axis X. The first elastic body 30 and the second elastic body 31 are offset with respect to each other both in the direction of the second axis Y and in the direction of the third axis Z. For example, the first elastic body 30 extends adjacent to the respective transduction mass 3a, 3b (for example the first transduction mass 3a, as in FIG. 6) and at a greater distance from the respective sensing mass 5a-5d (for example the first sensing mass 5a); vice versa, the second elastic body 31 extends adjacent to the respective sensing mass 5a-5d (here the first sensing mass 5a) and at a greater distance from the respective transduction mass 3a, 3b (here the first transduction mass 3a). Furthermore, the first elastic body 30 is closer to the substrate 7 than the second elastic body 31 (see also FIG. 3). For example, a lower edge of the first elastic body 30 is aligned in rest conditions, to a face of the first transduction mass 3a arranged facing the substrate 7; an upper edge of the second elastic body 31 is aligned with a face of the first sensing mass 5a arranged facing outwards. The first elastic body 30 and the second elastic body 31 have dimension, along the third axis Z, smaller than the transduction masses 3a, 3b and the sensing masses 5a-5d. The first elastic body 30 is connected to the respective connection flexure 26 at the first end of the motion conversion flexure 25; the second elastic body 31 is connected to the respective sensing mass 5a-5d (here the first sensing mass 5a) at the second end of the motion conversion flexure 25.

The transverse elements 35 are defined by flat plates of the same shape, for example rectangular, in rest conditions perpendicular to the first axis X. The elements are uniformly spaced along the first axis X and have first sides connected to the first elastic body 30 and second sides, opposite to the first sides, connected to the second elastic body 31.

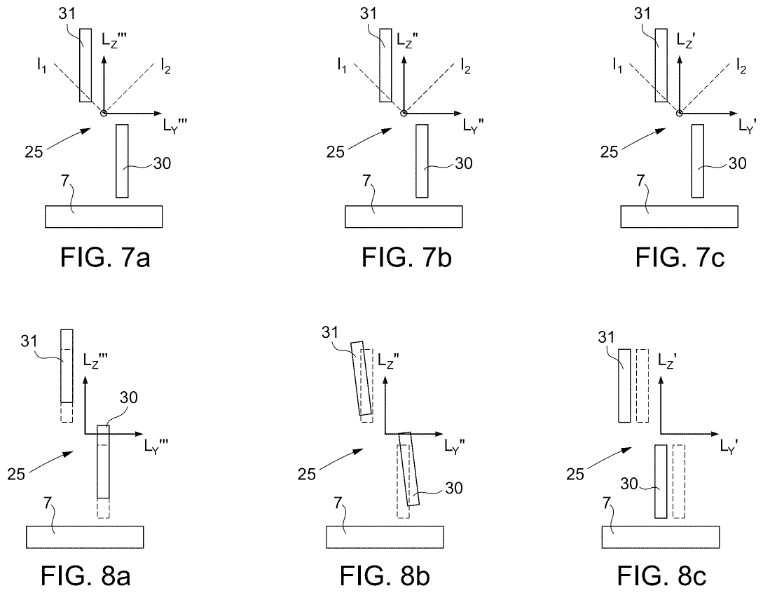

FIGS. 7a-7c show, by way of example, cross-sections of the motion conversion flexure 25 along planes parallel to the plane YZ at the first end, at a median portion and at the second end, respectively. In each of the FIGS. 7a-7c the main axes of inertia I1, I2 of the corresponding section of the first motion conversion flexure 25 are also shown, in the hypothesis that this section has infinitesimal thickness. In rest conditions, in particular, the main axes of inertia I1, I2 have a same orientation in each section and are misaligned and transverse with respect to both the second axis Y and the third axis Z. FIGS. 7a-7c also show, in rest conditions, pairs of local axes (indicated respectively by Ly′-Lz′, Ly″-Lz″ and Ly′″-Lz′″), each pair being formed by axes parallel to the second axis Y and the third axis Z, respectively, and passing through the barycenter of the section shown.

For each section of the first motion conversion flexure 25, a centrifugal moment of inertia Ic may be calculated, with respect to the corresponding pair of local axes, through the integral:

$${I}_{C} = \int \int {r}_{1} {r}_{2} dA$$

where r1 and r2 represent the distance of each point of the section from a first and a second axis of the pair of local axes respectively, while dA is the area unit of the section. The centrifugal moment of inertia Ic is non-zero, since the local axes are not axes of symmetry of the section and therefore do not coincide with the main axes of inertia I1, I2. In particular, the main axes of inertia I1, I2 form an angle β with the local axis parallel to the third axis Z and with the local axis parallel to the second axis Y, respectively.

Consequently, as may be seen in FIGS. 8a-8c, a force applied on the motion conversion flexure 25, for example along the local axis Lz″, causes a skew bending of the motion conversion flexure 25. In particular, this force causes a deformation along the local axis Lz″, which entails a resulting deformation along the local axis Ly″. Compared to the rest positions, represented with a dashed line, in response to a displacement of the first end of the motion conversion flexure 25 along the third axis Z (FIG. 7a), the skew bending causes a rototranslation of the median section (FIG. 7b) and the translation of the second end in the direction of the second axis Y. Due to the skew bending, the motion along the third axis Z caused by the transduction masses 3a, 3b to the first ends of the motion conversion flexures 25 in response to a rotation around the sensing axis S is converted into a corresponding motion along the second axis Y of the second ends of the motion conversion flexures 25 and therefore of the sensing masses 5a-5d.

The constraints represented by the suspension flexures 17, 21 and by the connection flexures 26 favor the skew bending of the motion conversion flexures 25 and facilitate the correct movement of the sensing masses 5a-5d.

When the support body 2 rotates around the sensing axis S, the transduction masses 3a, 3b oscillate along the transduction direction DT and the third axis Z at the driving frequency ωD, in phase-opposition (i.e., in opposite directions) and with amplitude proportional to the angular velocity Ω. The motion conversion flexures 25 convert the oscillations of the transduction masses 3a, 3b along the third axis Z into corresponding oscillations of the sensing masses 5a-5d along the second axis Y, which may be read through the capacitive coupling between the movable sensing electrodes 22 and fixed sensing electrodes 23a, 23b. In more detail, the first sensing mass 5a and the second sensing mass 5b oscillate in phase-opposition with each other, as well as the third sensing mass 5c and the fourth sensing mass 5d. Furthermore, the first sensing mass 5a and the fourth sensing mass 5d oscillate in-phase with each other. Similarly, the second sensing mass 5b and the third sensing mass 5c oscillate in-phase with each other both due to the action of the motion conversion flexures 25 and, in addition, obviously due to the fact that they are constrained to each other to form a single rigid body. The movement of the second sensing mass 5b and the third sensing mass 5c would still be in-phase even in the absence of a rigid constraint therebetween.

The gyroscope described herein may therefore be used to sense rotations around pitch or roll axes of the support body, in addition implementing also a fully differential structure in the plane thanks to the conversion of the out-of-plane motion of the transduction masses 3a-3b into the in-plane motion of the sensing masses 5a-5d. This therefore allows the advantages of fully differential structures to be extended also to gyroscopes wherein the transduction of the rotation originally generates an out-of-plane movement (in fact, when rotations around pitch or roll axes are sensed). In particular, the gyroscope described herein allows improvement of the rejection of common-mode contributions and the stability of the scale factor following external events, such as thermal or mechanical stresses, that may deform the substrate.

Finally, it is clear that modifications and variations may be made to the gyroscope described and illustrated herein without thereby departing from the scope of this disclosure, as defined in the attached claims.

1. A microelectromechanical gyroscope, comprising:
a support body having a main surface parallel to a reference plane defined by a first axis and a second axis perpendicular to each other;
a plurality of transduction masses constrained to the support body so as to be capable of oscillating along a driving direction parallel to the first axis and along a third axis perpendicular to the first axis and the second axis;
a plurality of sensing masses constrained to the support body at a distance from a substrate so as to be capable of oscillating in a direction parallel to the second axis; and
a plurality of motion conversion flexures, each motion conversion flexure connecting one of the plurality of transduction masses to one of the plurality of sensing masses and configured to convert movements of the one of the plurality of transduction masses along the third axis into movements of the one of the plurality of sensing masses along the second axis.

2. The microelectromechanical gyroscope according to claim 1, wherein the plurality of transduction masses comprise a first transduction mass and a second transduction mass arranged symmetrically opposite to each other, in rest conditions, with respect to a reference axis parallel to the first axis.

3. The microelectromechanical gyroscope according to claim 2, comprising:
a plurality of first anchors fixed to the support body; and
a plurality of oscillating arms, each oscillating arm of the plurality of oscillating arms supported by one of the plurality of first anchors around a fulcrum so as to oscillate parallel to the reference plane, wherein the fulcrums are aligned along the reference axis in symmetrically opposite positions with respect to a median axis of the plurality of transduction masses parallel to the second axis;
wherein the first transduction mass and the second transduction mass are supported by the plurality of oscillating arms so as to be movable parallel to the first axis and parallel to the third axis.

4. The microelectromechanical gyroscope according to claim 3, wherein the plurality of oscillating arms are coupled to the plurality of transduction masses so as to allow phase-opposition movements and prevent in-phase movements of the first transduction mass and the second transduction mass along the first axis.

5. The microelectromechanical gyroscope according to claim 3, wherein each oscillating arm of the plurality of oscillating arms has:
a first end connected to the first transduction mass; and
a second end connected to the second transduction mass through a plurality of first suspension flexures, wherein the plurality of first suspension flexures are configured to convey movements from the first and second ends of the plurality of oscillating arms to the first and second transduction masses in the direction of the first axis.

6. The microelectromechanical gyroscope according to claim 3, wherein each oscillating arm of the plurality of oscillating arms is coupled to one of the plurality of first anchors with its fulcrum in a symmetrically opposite position with respect to the median axis.

7. The microelectromechanical gyroscope according to claim 3, comprising:
a plurality of second anchors; and
a plurality of second suspension flexures;
wherein each sensing mass of the plurality of sensing masses is supported by one of the plurality of second anchors through one of the plurality of second suspension flexures, and wherein the plurality of second suspension flexures are yielding in the direction of the second axis and rigid in the direction of the first axis and the third axis.

8. The microelectromechanical gyroscope according to claim 2, wherein the plurality of sensing masses comprise:
a first sensing mass and a second sensing mass coupled to the first transduction mass; and
a third sensing mass and a fourth sensing mass coupled to the second transduction mass;
wherein the first and second sensing masses are adjacent to opposite sides of the first transduction mass, and the third and fourth sensing masses are adjacent to opposite sides of the second transduction mass.

9. The microelectromechanical gyroscope according to claim 8, wherein the second sensing mass and the third sensing mass form a single rigid body.

10. The microelectromechanical gyroscope according to claim 8, wherein:
the motion conversion flexures connecting the first transduction mass to the first and second sensing masses are configured to cause movements of the first and second sensing masses in phase-opposition in response to displacements of the first transduction mass along the third axis; and
the motion conversion flexures connecting the second transduction mass to the third and fourth sensing masses are symmetrical to each other and are configured to cause movements of the third and fourth sensing masses in phase-opposition in response to displacements of the second transduction mass along the third axis.

11. The microelectromechanical gyroscope according to claim 8, wherein each motion conversion flexure of the plurality of motion conversion flexures has:
an elongated shape in the direction of the first axis;
a first end connected to one of the plurality of transduction masses; and
a second end connected to one of the plurality of sensing masses.

12. The microelectromechanical gyroscope according to claim 11, wherein the first end of each motion conversion flexure is coupled to its associated transduction mass through a connection flexure that is rigid along the third axis and yielding along the driving direction parallel to the first axis.

13. The microelectromechanical gyroscope according to claim 1, wherein the plurality of motion conversion flexures are of a skew bending type.

14. The microelectromechanical gyroscope according to claim 1, wherein each motion conversion flexure of the plurality of motion conversion flexures comprises:
a first elastic body;
a second elastic body; and
a plurality of transverse elements;
wherein:
the first elastic body and the second elastic body are defined by flat rectangular plates, in rest conditions perpendicular to the second axis and elongated in the direction of the first axis; and
the first elastic body and the second elastic body are offset with respect to each other in the direction of the second axis and in the direction of the third axis.

15. The microelectromechanical gyroscope according to claim 11, wherein each motion conversion flexure of the plurality of motion conversion flexures comprises:
a first elastic body;
a second elastic body; and
a plurality of transverse elements;
wherein:
the first elastic body and the second elastic body are defined by flat rectangular plates, in rest conditions perpendicular to the second axis and elongated in the direction of the first axis; and
the first elastic body and the second elastic body are offset with respect to each other in the direction of the second axis and in the direction of the third axis; and
wherein for each motion conversion flexure of the plurality of motion conversion flexures:
the first elastic body is connected to the associated transduction mass at the first end of the motion conversion flexure; and
the second elastic body is connected to the associated sensing mass at the second end of the motion conversion flexure.

16. The microelectromechanical gyroscope according to claim 14, wherein:
the plurality of transverse elements are defined by flat plates in rest conditions perpendicular to the first axis;
the plurality of transverse elements are uniformly spaced along the first axis; and
each transverse element of the plurality of transverse elements has a first side connected to the first elastic body and a second side, opposite to the first side, connected to the second elastic body.

17. The microelectromechanical device according to claim 15, wherein each actuator comprises:
fixed electrodes anchored to the substrate; and
movable electrodes interdigitated with the fixed electrodes to form capacitive coupling elements.

18. The microelectromechanical device according to claim 17, wherein:
the first pair of actuators comprises rows of the capacitive coupling elements offset along a first direction; and
the second pair of actuators comprises rows of the capacitive coupling elements offset along a second direction perpendicular to the first direction.

19. The microelectromechanical device according to claim 17, wherein a capacitance value of each actuator depends on displacement along a single coordinate axis parallel to the substrate.

20. The microelectromechanical device according to claim 17, wherein each actuator comprises multiple rows of the capacitive coupling elements, with fixed and movable electrodes in each row being offset from each other along a direction perpendicular to the row's direction.

21. A method of operating a microelectromechanical gyroscope, comprising:
driving first and second transduction masses to oscillate in phase-opposition along a driving direction parallel to a first axis at a driving frequency;
in response to rotation of the microelectromechanical gyroscope about a sensing axis parallel to a second axis perpendicular to the first axis, generating out-of-plane motion of the first and second transduction masses along a third axis perpendicular to both the first and second axes;
converting, through motion conversion flexures, the out-of-plane motion of the first and second transduction masses along the third axis into in-plane motion of sensing masses along the second axis; and
sensing the in-plane motion of the sensing masses through a differential sensing structure to determine an angular velocity of the rotation.

22. The method according to claim 21, wherein:
the sensing masses comprise first and second sensing masses coupled to the first transduction mass and third and fourth sensing masses coupled to the second transduction mass; and
converting the out-of-plane motion comprises:
converting motion of the first transduction mass to cause the first and second sensing masses to move in phase-opposition along the second axis; and
converting motion of the second transduction mass to cause the third and fourth sensing masses to move in phase-opposition along the second axis.

23. The method according to claim 22, wherein:
the first sensing mass and the fourth sensing mass move in-phase with each other along the second axis; and
the second sensing mass and the third sensing mass move in-phase with each other along the second axis.

24. The method according to claim 21, wherein converting the out-of-plane motion comprises:
applying a force to a first end of each motion conversion flexure to cause skew bending of the motion conversion flexure; and
generating, through the skew bending, a displacement of a second end of each motion conversion flexure along the second axis in response to displacement of the first end along the third axis.

25. The method according to claim 24, wherein:
each motion conversion flexure comprises a first elastic body and a second elastic body offset from each other in the direction of the second axis and the third axis; and
the skew bending comprises deformation of the first and second elastic bodies along main axes of inertia that are misaligned with the second and third axes.

26. The method according to claim 21, further comprising:
applying a driving voltage to the first and second transduction masses with opposite polarities to generate electrostatic forces causing the phase-opposition oscillation along the first axis.
